(19) United States
(12) Patent Application Publication
(10) Pub. No.: US 2007/0034893 A1
(43) Pub. Date: Feb. 15, 2007

(54) Solid-state image pickup device and manufacturing method of the same

(75) Inventor: Yoshimitsu Nakashima, Nara-Ken (JP)

Correspondence Address: EDWARDS & ANGELL, LLP, P.O. BOX 55874, BOSTON, MA, 02205, US

(73) Assignee: Sharp Kabushiki Kaisha, Osaka (JP)

(21) Appl. No.: 11/501,497

(22) Filed: Aug. 8, 2006

(30) Foreign Application Priority Data
Aug. 11, 2005 (JP) 2005-233246

(51) Int. Cl. H01L 31/111; H01L 29/74; H01L 29/417

(52) U.S. Cl. 257/113

(57) ABSTRACT

In a solid-state image pickup device according to the present invention, groove-like recesses are formed on a semiconductor substrate, and first wiring for vertical transfer electrode use are formed in the groove-like recesses, in order to reduce the distance between the semiconductor substrate and the microlens. According to the solid-state image pickup device, difference in level of a CCD image sensor caused by overlapping the first and second wirings for vertical transfer electrode use can be eliminated, and thereby the distance between the photoelectric conversion elements and the microlens can be reduced, and thus the sensitivity of the CCD image sensor can be reduced.

### CROSS-REFERENCE TO RELATED APPLICATIONS

This nonprovisional application claims priority under 35 U.S.C. §119(a) on Patent Application No(s). 2005-233246 filed in Japan on Aug. 11, 2005, the entire contents of which are hereby incorporated by reference.

### BACKGROUND OF THE INVENTION

The present invention relates to a solid-state image pickup device, and in particular to a solid-state image pickup device having a high sensitivity, and a manufacturing method of the same.

In recent years, solid-state image pickup devices used for mobile phones, digital still cameras, digital video cameras, etc. have been decreasing in size and increasing in pixel density steadily. CCD image sensors included in solid-state image pickup devices have also been decreasing in size and increasing in pixel density, and therefore the pixel area has been decreasing, the opening for the light-blocking film of the light-receiving section has been becoming small, and the sensitivity has been decreasing.

As a means of increasing the sensitivity, there is a way to reduce the distance between the semiconductor substrate and the microlens. However, CCD image sensors have a structure in which electrodes, a light-blocking film, a planarization film, a color filter, and a microlens are laminated, so that it is difficult to reduce the distance between the microlens and the semiconductor substrate by a simple method.

The structure of a conventional CCD image sensor will be described with reference to FIG. 8. The CCD image sensor roughly consists of divided into a light-receiving section 101, a horizontal CCD 102, and an output section 103. In the light-receiving section 101, elements (photoelectric conversion elements 104) for performing photoelectric conversion and storing signal charges generated are arranged in a matrix form. In addition, vertical CCDs 105 are provided each consisting of a vertical charge-transfer section for transferring signal charges in the vertical direction along a column of photoelectric conversion elements 104, and vertical transfer electrodes for controlling the transfer of charges.

Next, the operation of the CCD image sensor will be described. Incident light on the CCD image sensor is converted to signal charges by the photoelectric conversion elements 104. The signal charges obtained by photoelectric conversion of the photoelectric conversion elements 104 are stored in the photoelectric conversion elements 104. The signal charges stored in the photoelectric conversion elements 104 are read out to the vertical CCDs 105. The signal charges read out to the vertical CCDs are transferred to the horizontal CCD 102 every one horizontal row of photoelectric conversion elements, that is, every one horizontal line. Signal charges transferred to the horizontal CCD 102 are transferred to the output section 103, and are then output to the CDS (correlated double sampling) circuit.

Next, the structure of wirings for vertical transfer electrode use of the CCD image sensor will be described with reference to FIGS. 9 to 11. FIG. 9 is a schematic partial plan view showing the wiring structure. First wirings for vertical transfer electrode use 106 are provided across the image sensor field in the horizontal direction between photoelectric conversion elements 104 which are adjacent to each other in the vertical direction. Areas where first wirings for vertical transfer electrode use 106 overlap vertical charge-transfer sections 112 constitute first transfer electrodes 110 (areas each surrounded by a chain double-dashed line in the figure). Second wirings for vertical transfer electrode use 107 are also provided in the horizontal direction between photoelectric conversion elements 104 which are adjacent to each other in the vertical direction, and both horizontal-side ends of photoelectric conversion element 104 are on ends of the first and second wirings for vertical transfer electrode use 106, 107. Areas obtained by excluding areas where first wirings for transfer electrode use 106 overlap vertical charge-transfer sections 112 from areas where second wirings for transfer electrode use 107 overlap vertical charge-transfer sections 112 constitute second transfer electrodes 111 (areas each surrounded by a chain double-dashed line in the figure). Second wirings for vertical transfer electrode use 107 also serve as transfer gate electrodes for reading out signal charges from photoelectric conversion elements 104 to vertical charge-transfer sections 112.

FIG. 10 is a schematic cross-sectional view at areas with the vertical CCDs cut vertically along the line A-A′ shown in FIG. 9. On the top surfaces of vertical charge-transfer sections 112 formed by ion implantation to or heat treatment of the semiconductor substrate, first wirings for vertical transfer electrode use 106 and second wirings for vertical transfer electrode use 107 are provided via an insulating film. Second wirings for vertical transfer electrode use 107 are provided so as to partially run up on first wirings for vertical transfer electrode use 106, in order to prevent gaps 110 between first wirings for vertical transfer electrode use 106 and second wirings for vertical transfer electrode use 107 from becoming large due to variations in manufacturing such as alignment deviations at patterning. When the gaps become large, the charge transfer efficiency deteriorates, and the picture quality is lowered.

Next, FIG. 11 shows a schematic cross-sectional view at a center of the photoelectric conversion element 104 cut vertically along the line B-B′ shown in FIG. 9. First wirings for vertical transfer electrode use 106 are formed via insulating films on areas separating adjacent photoelectric conversion elements 104, and on the top surfaces of the first wirings, second wirings for vertical transfer electrode use 107 are formed via insulating films. As can be seen from FIGS. 9 and 10, second wirings for vertical transfer electrode use 107 have portions which run up on first wirings for vertical transfer electrode use 106, and other portions which do not run up on them, which causes the second wirings for vertical transfer electrode use 107 to have a difference in level. Consequently, it has been becoming difficult to etch the second wirings for vertical transfer electrode use made of polycrystalline silicon films. A light-blocking film 108 is formed to cover the wirings for vertical transfer electrode use 106, 107, and a planarization film 109 is formed on the light-blocking film 8. Like this, in the conventional CCD image sensor, electrodes partially overlap each other, and many films such as the light-blocking film and the planarization film are laminated, so that the distance from the semiconductor substrate to the microlens becomes long.

Next, a method of manufacturing the conventional CCD image sensor will be described.

FIG. 12 shows a schematic cross-sectional process view with a vertical CCD cut in the vertical direction along the line A-A′ shown in FIG. 9.

Vertical charge-transfer sections 112 are formed on a semiconductor substrate 101 by ion implantation or heat treatment (FIG. 12A). Subsequently, a gate oxide film as an insulating film is formed on the semiconductor substrate, and then a polycrystalline silicon film which will be first wirings for vertical transfer electrode use 106 is deposited by chemical vapor deposition (CVD), and first wirings for vertical transfer electrode use 106 are then formed by doping, patterning, etching, etc. (FIG. 12B) Subsequently, a gate oxide film as an insulating film is formed again, and then a polycrystalline silicon film which will be second wirings for vertical transfer electrode use 107 is deposited by CVD, and second wirings for vertical transfer electrode use 107 are then formed by doping, patterning, etching, etc. (FIG. 12C). Subsequently, titanium nitride (TiN), tungsten (W), etc. which will be a light-blocking film 108 are deposited by sputtering or CVD, and a light-blocking film 108 is then formed by patterning and etching so as not to cover portions which will be photoelectric conversion elements 104. Subsequently, the photoelectric conversion elements 104 are formed by ion implantation or heat treatment. Subsequently, a planarization film 109 is formed (FIG. 12D). In the case of a color CCD image sensor, acrylic material is additionally applied, and then a color filter (not shown) for the photoelectric conversion elements is formed, and moreover acrylic material is applied to form a planarization film as a protective film (not shown). Subsequently, lens material is applied, and a microlens (not shown) is then formed by patterning and heat treatment.

By the way, a method of reducing the distance between the semiconductor substrate and the microlens is proposed in Japanese Laid-open Patent Publication No. 9-237888. In Japanese Laid-open Patent Publication No. 9-237888, as shown in FIG. 13, a solid-state image pickup device is proposed in which two electrode layers are disposed in the same layer to eliminate overlap of electrodes in such a manner that first wirings for vertical transfer electrode use 106 are formed by lithography, and then second wirings for vertical transfer electrode use 107 are deposited.

The reason why the distance from the semiconductor substrate to the microlens is long in the conventional CCD image sensor is that the second wirings for vertical transfer electrode use 107 are formed so as to partially and overlay the first wirings for vertical transfer electrode use 106, and it has a laminate structure using many films such as the light-blocking film 108, planarization film 109 and color filter. However, films such as the light-blocking film, planarization film, and color filter used in the conventional CCD image sensor are indispensable, and several ways to reduce film thickness have also been adopted, and reducing film thickness has been becoming very difficult more than ever before. Because of this, it has been required to eliminate overlap of transfer electrodes.

However, in Japanese Laid-open Patent Publication No. 9-237888, as shown in plan view of FIG. 13, two layers of electrodes are disposed in the same layer, but do not overlap each other vertically with respect to the substrate. Because of this, in regions where the two layers of electrodes have to be disposed in parallel, particularly in regions where they are wired in the horizontal direction in the gap N between photoelectric conversion elements which are adjacent to each other in the vertical direction, both of the two layers of electrodes have to become narrow wirings. As a result, the wiring resistance of electrodes becomes large, which causes deterioration of the charge transfer efficiency. Furthermore, since either of the two layers of electrodes is adjacent to the substrate via an oxide film only, variations of read out voltage in the wirings for electrodes affects adjacent elements, which may deteriorate the picture quality.

### SUMMARY OF THE INVENTION

Therefore, an object of the present invention is to provide a solid-state image pickup device capable of reducing the distance between the photoelectric conversion elements and the microlens in the light-receiving section without causing the above-mentioned deterioration of the picture quality.

In order to achieve the above object, groove-like recesses are arranged on the surface of the semiconductor substrate, and first wirings for vertical transfer electrode use are formed in the groove-like recesses. Since first wirings for vertical transfer electrode use are formed in the groove-like recesses, the distance between the semiconductor substrate and the microlens can be reduced.

Furthermore, by forming first wirings for vertical transfer electrode use in groove-like recesses formed on the surface of the semiconductor substrate, and aligning the surfaces of the first wirings for vertical transfer electrode use with the surface of the substrate in the same plane, the protruding height above the substrate surface corresponding to the height of the first wirings for vertical transfer electrode use can be eliminated, and thereby the distance between the semiconductor substrate and the microlens can be reduced.

In order to achieve the above object, there is provided a solid-state image pickup device comprising a light-receiving section having photoelectric conversion elements arranged in a matrix form, and more than two layers of wirings for vertical transfer electrode use provided along a transfer direction in order to transfer signal charges in the vertical direction along photoelectric conversion element columns of the light-receiving section, wherein the first wirings for vertical transfer electrode use include areas positioned at the same depth below a surface of a semiconductor substrate as that of both the photoelectric conversion elements and the vertical charge-transfer sections facing wirings other than the first wirings for vertical transfer electrode use. Also in this case, the protruding height above the surface of the semiconductor substrate corresponding to the height of the first wirings for vertical transfer electrode use can be reduced, and thereby the distance between the semiconductor substrate and the microlens can be reduced.

Also, there is provided a manufacturing method of a solid-state image pickup device which has a light-receiving section having photoelectric conversion elements arranged in a matrix form, and a vertical charge-transfer section for transferring signal charges in the vertical direction along the photoelectric conversion element columns of the light-receiving section, and which has more than two layers of wirings for vertical transfer electrode use provided on the vertical charge-transfer section via insulating films along a transfer direction, the method comprising a process of forming groove-like recesses on a semiconductor substrate, and a process of forming the first wirings for vertical transfer electrode use in the groove-like recesses. According to this manufacturing method, a solid-state image pickup device can be easily manufactured in which the first wirings for vertical transfer electrode use include the areas positioned at the same depth below the surface of the semiconductor substrate as that of both the photoelectric conversion elements and the vertical charge-transfer sections facing wirings other than the first wirings for vertical transfer electrode use.

In this case, by aligning the upper surface of the first wiring for vertical transfer electrode use with the surface of the semiconductor substrate in the same plane by chemical and mechanical polishing, the difference in level between surfaces of the first wirings for vertical transfer electrode use and the semiconductor substrate can be eliminated. Consequently, the second wirings for vertical transfer electrode use are easily formed.

According to the present invention, the difference in level caused by overlapping the first and second wirings for vertical transfer electrode use can be reduced, and thereby the distance between the photoelectric conversion elements and the microlens can be reduced, and consequently a solid-state pickup device having a better sensitivity can be provided.

### BRIEF DESCRIPTION OF THE DRAWINGS

The present invention will become more fully understood from the detailed description given herein below and the accompanying drawings which are given by way of illustration only, and thus are not intended to limit the present invention, and wherein:

FIG. 1 is a schematic plan view showing the wiring structure of the light-receiving section of embodiment 1 of the present invention.

FIG. 2 is a schematic cross-sectional view taken along the line C-C′ in FIG. 1 of embodiment 1 of the present invention.

FIG. 3 is a schematic cross-sectional view taken along the line D-D′ in FIG. 1 of embodiment 1 of the present invention.

FIG. 4 is a schematic cross-sectional view illustrating the manufacturing process of embodiment 1 of the present invention.

FIG. 5 is a schematic plan view showing the wiring structure of the light-receiving section of embodiment 2 of the present invention.

FIG. 6 is a schematic cross-sectional view taken along the line F-F′ in FIG. 5 of embodiment 2 of the present invention.

FIG. 7 is a schematic cross-sectional view taken along the line E-E′ in FIG. 5 of embodiment 2 of the present invention.

FIG. 8 is a schematic diagram showing a rough structure of a conventional solid-state image pickup device.

FIG. 9 is a schematic plan view showing the wiring structure of a conventional light-receiving section.

FIG. 10 is a schematic cross-sectional view taken along the line A-A′ in FIG. 9.

FIG. 11 is a schematic cross-sectional view taken along the line B-B′ in FIG. 9.

FIGS. 12A to 12D are schematic cross-sectional views illustrating a conventional manufacturing process.

FIG. 13 is a schematic plan view of the light-receiving section disclosed in Japanese Laid-open Patent Publication No. 9-237888.

### DETAILED DESCRIPTION OF THE INVENTION

### Embodiment 1

The first embodiment (embodiment 1) of the present invention will be described below. Embodiment 1 is a CCD image sensor having a light-receiving section 101, a horizontal CCD section 102, and an output section 103. Since all the components of the image sensor are substantially similar to those of the conventional structure shown in FIG. 8, and the operation of the CCD image sensor is similar to that of the conventional structure, there is a case that description regarding points similar to FIG. 8 is omitted.

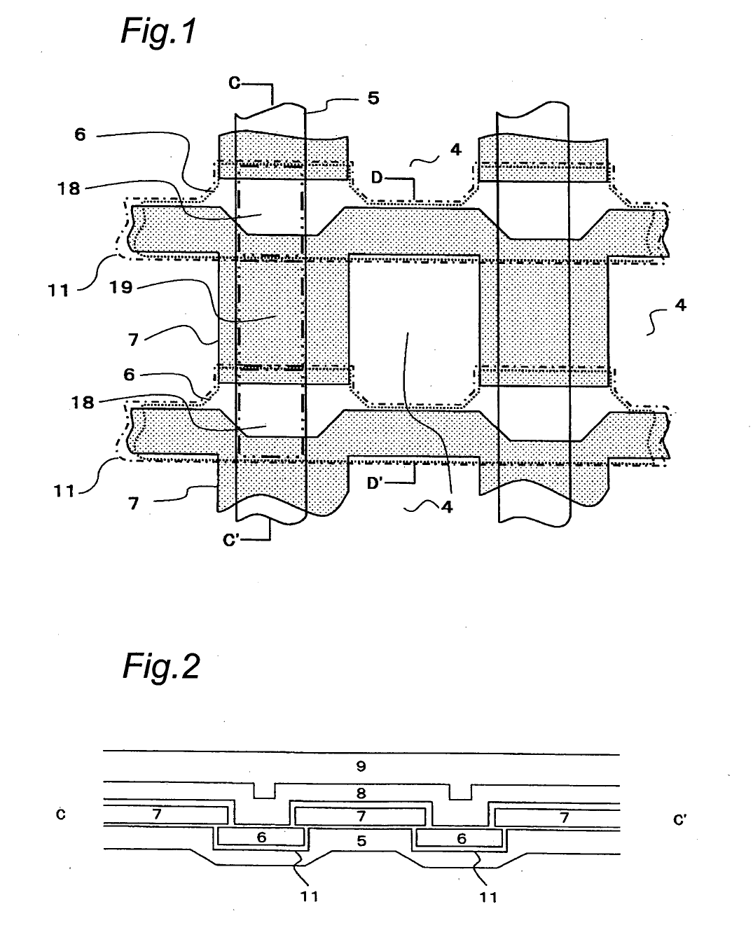

FIG. 1 is a schematic plan view showing the wiring structure of the light-receiving section of the CCD image sensor of embodiment 1. In this embodiment, a plurality of elements (photoelectric conversion elements 4) for performing photoelectric conversion and storing signal charges generated are arranged in a matrix form. And, vertical charge-transfer sections 5 are formed along and in the proximity of the columns of the photoelectric conversion elements 4 of the light-receiving section 101.

First wirings for vertical transfer electrode use 6 are provided across the whole of the light-receiving section 101 of the image sensor in the horizontal direction between photoelectric conversion elements 4 which are adjacent to each other in the vertical direction. Portions of wirings 6 facing vertical charge-transfer sections 5 extend upstream, and end portions of the extended portions overlap, via insulating films, downstream end portions of second wirings for vertical transfer electrode use 7 located upstream side of the extended portions. The downstream ends of the portions of wirings 6 facing vertical charge-transfer sections 5 face second wirings for vertical transfer electrode use 7 via insulating films. Areas where the first wirings for vertical transfer electrode use 6 overlap the vertical charge-transfer sections 5 constitute first transfer electrodes 18 (areas each surrounded by a chain double-dashed line in the figure).

Second wirings for vertical transfer electrode use 7 are also provided across the whole of the light-receiving section 101 of the image sensor in the horizontal direction between photoelectric conversion elements 4 which are adjacent to each other in the vertical direction. Portions of wirings 7 facing vertical charge-transfer sections 5 are so shaped that the upstream portions of them are recessed in the downstream direction, and these recesses face the downstream ends of first wirings for vertical transfer electrode use 6 via insulating films. End portions extending from the downstream portions of the wirings 7 in the downstream direction reach near the downstream ends of the photoelectric conversion elements 4. The end portions overlap, via insulating films, the upstream end portions of the first wirings for vertical transfer electrode use 6 located downstream side of the end portions.

Areas obtained by excluding areas where first wirings for transfer electrode use 6 overlap vertical charge-transfer sections 5 from areas where second wirings for transfer electrode use 7 overlap vertical charge-transfer sections 5 constitute second transfer electrodes 19 (areas each surrounded by a chain double-dashed line in the figure). Second wirings for vertical transfer electrode use 7 also serve as transfer gate electrodes for reading out signal charges from photoelectric conversion elements 4 to vertical charge-transfer sections 5.

FIG. 2 is a schematic cross-sectional view with the vertical CCDs cut in the vertical direction along the line C-C′ shown in FIG. 1. The CCD image sensor of this embodiment has, as shown in FIG. 2, groove-like recesses 11 shaped along first wirings for vertical transfer electrode use 6 on the semiconductor substrate. On the semiconductor substrate on which recesses 11 are formed, vertical charge-transfer sections 5 extending in the direction perpendicular to the extending direction of the recesses 11 are provided. The first wirings for vertical transfer electrode use 6 are provided in the groove-like recesses of the semiconductor substrate astride vertical charge-transfer sections 5 arranged in a column. Since the first wirings for vertical transfer electrode use 6 are provided in the recesses 11, the difference in level between the first wirings for vertical transfer electrode use 6 and the semiconductor substrate can be reduced as compared with the conventional one. As a result, the distance between the photoelectric conversion elements 4 and the microlens can be reduced, so that the sensitivity of the CCD image sensor can be increased. The configuration resulting in this effect is, in other words, the configuration in which the first wirings for vertical transfer electrode use 6 are arranged in the same layer as the photoelectric conversion elements 4 and the vertical charge-transfer sections 5.

In order to increase the sensitivity, it is preferred to planarize such that the surface of the semiconductor substrate and the surfaces of the first wirings for vertical transfer electrode use 6 are in the same plane, as is the case in this embodiment 1. As a result, taking no account of the gate oxide film, the upper surface of the first wirings for vertical transfer electrode use 6 aligns with the lower surface of the second wirings for vertical transfer electrode use 7 on the semiconductor substrate, and thus the distance between the photoelectric conversion elements 4 and the microlens can be further reduced.

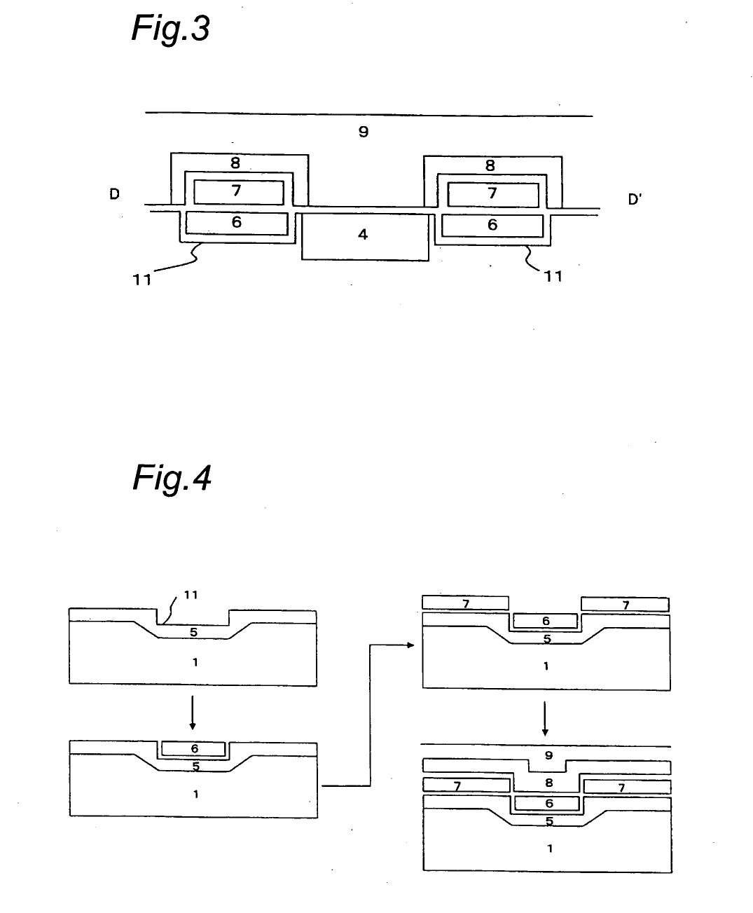

Next, FIG. 3 shows a schematic cross-sectional view with the central part of light-receiving section cut vertically along the line D-D′ shown in FIG. 1. In regions which separate photoelectric conversion elements 4 being adjacent to each other in the vertical direction, groove-like recesses 11 are formed. The groove-like recesses are formed such that first wirings for vertical transfer electrode use 6 are provided therein and the surface of the semiconductor substrate and the surfaces of the first wirings for vertical transfer electrode use 6 are in the same plane. On the first wirings for vertical transfer electrode use 6, second wirings for vertical transfer electrode use 7 are formed via insulating films. A light-blocking film 8 is formed to cover the first wirings for vertical transfer electrode use 6 and the second wirings for vertical transfer electrode use 7, and a planarization film 9 is formed on the light-blocking film 8.

Next, a manufacturing method of this embodiment will be described with reference to FIG. 4. Groove-like recesses 11 having the depth of about 3000 Å are formed by etching on portions of the semiconductor substrate 1 in which first wirings for vertical transfer electrode use will be provided later. Next, vertical charge-transfer sections 5 constituting vertical CCDs are formed by ion implantation or heat treatment. Next, a gate oxide film for first wirings for vertical transfer electrode use 6 is formed on the whole surface of the semiconductor substrate including the recess surfaces, and a polycrystalline silicon film having the thickness of about 4000 Å is then deposited on the gate oxide film by CVD, and the first wirings for vertical transfer electrode use 6 are formed. Subsequently, the first wirings for vertical transfer electrode use 6 are cut by chemical and mechanical polishing until the surface of the semiconductor substrate and the surfaces of the first wirings for vertical transfer electrode use are planarized to be in the same plane. Next, a gate oxide film for second wirings for vertical transfer electrode use 7 is formed, and a polycrystalline silicon film having the thickness of about 4000 Å which will be second wirings for vertical transfer electrode use 7 is then deposited, and subsequently second wirings for vertical transfer electrode use 7 are formed on the semiconductor substrate by patterning, etching, etc. At this time, the surfaces of the first wirings for vertical transfer electrode use 6 are in the same plane as the surface of the semiconductor substrate, so that there is no difference in level in the second wirings for vertical transfer electrode use 7, and thereby patterning, etching, etc. can be performed easily. Subsequently, TiN and W which will be a light-blocking film 8 are deposited with the thickness of about 1000 Å and the thickness of about 3000 Å, respectively, by CVD. Patterning, etching, etc. are performed to the TiN and W films so as to cover the first wirings for vertical transfer electrode use 6 and the second wirings for vertical transfer electrode use 7 to form a light-blocking film 8. Subsequently, boron phosphorus silicate glass (BPSG) is deposited with the thickness of about 5000 Å on the light-blocking film 8 by CVD. Subsequently, heat treatment at 850 to 950° C. is performed to the BPSG film and the surface of the BPSG film is made flat to form a planarization film 9. Next, acrylic material is applied and subsequently a color filter is formed, and then acrylic material is applied as a protective film to form a planarization film, which is not shown in the figure. Subsequently, lens material is applied and a microlens is formed by patterning and heat treatment. The above description is for a manufacturing method of a color CCD image sensor. In the case of a monochrome CCD image sensor, processes with regard to forming a color filter can be omitted.

### Embodiment 2

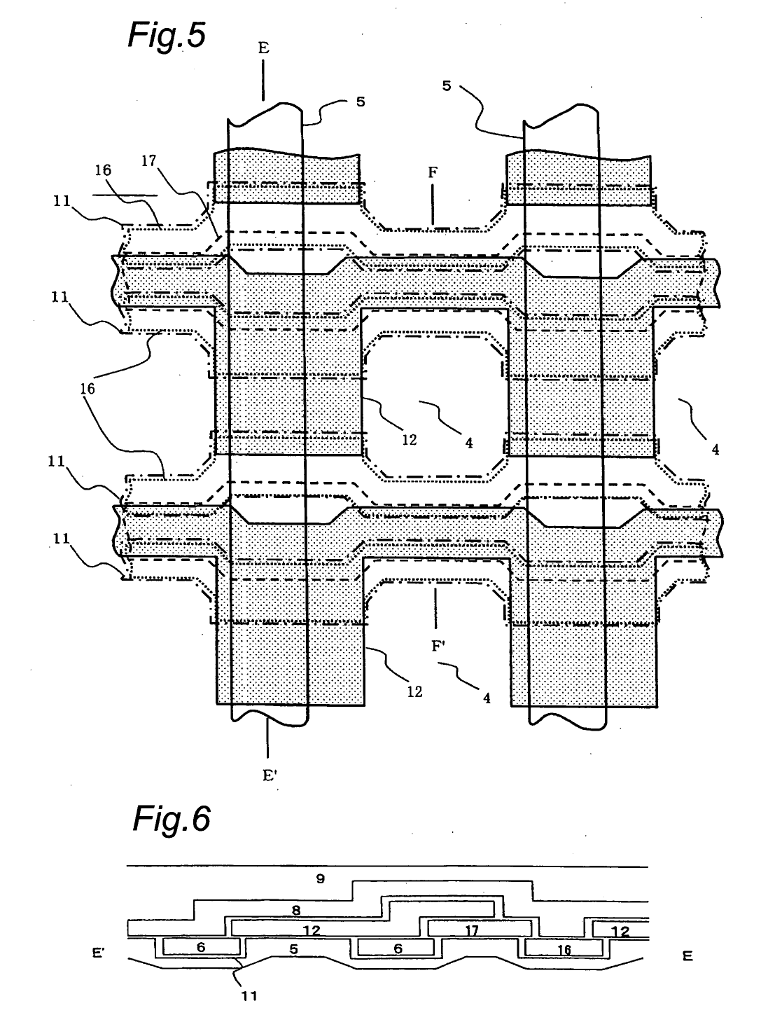

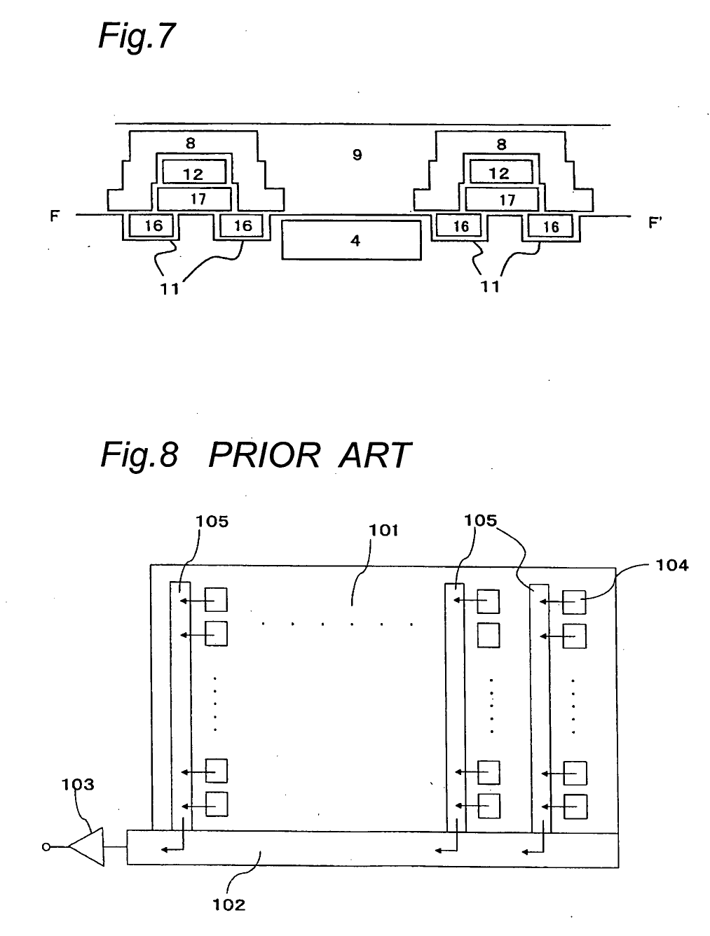

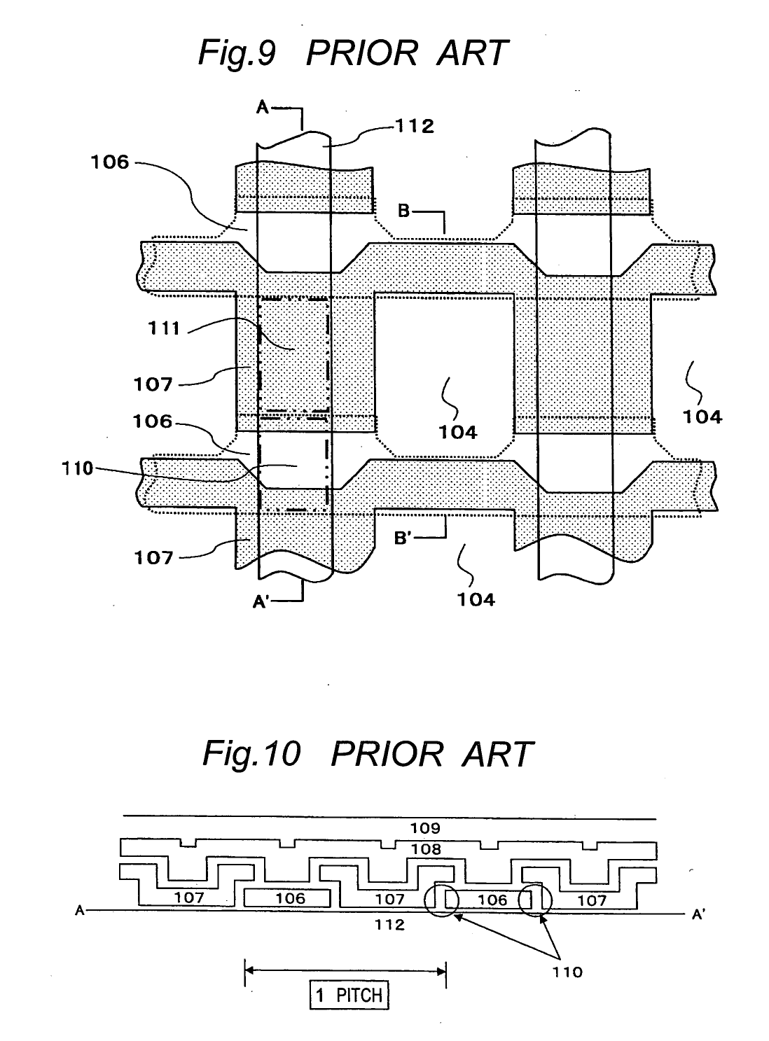

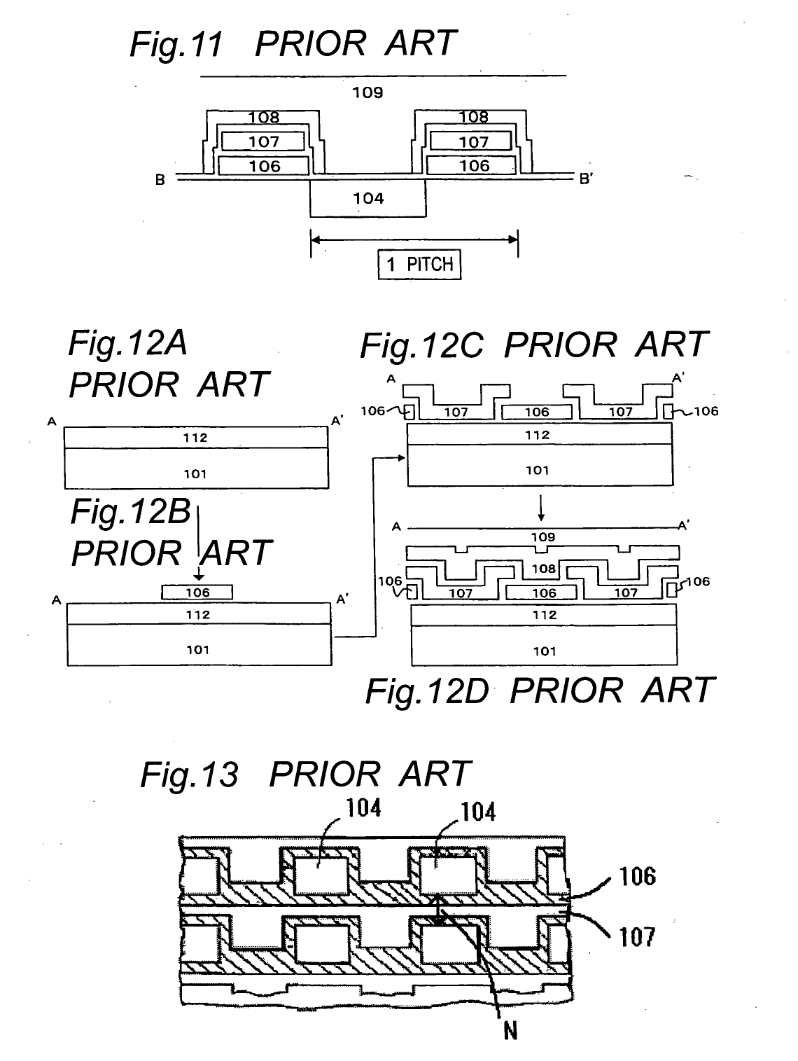

In embodiment 1, a CCD image sensor having two layers of wirings for vertical transfer electrode use is described. However, the present invention may also be achieved in a CCD image sensor having a structure in which three or more layers of wirings for vertical transfer electrode use are provided. FIG. 5 is a schematic plan view showing the wiring structure of the light-receiving section of an image sensor having three layers of wirings for vertical transfer electrode use. FIG. 6 is a cross-sectional view taken along the line E-E′ of embodiment 2 and FIG. 7 is a cross-sectional view taken along the line F-F′ of embodiment 2 shown respectively in FIG. 5. In embodiment 2, description about the same constituent as embodiment 1 is omitted with the same numeral attached thereto.

In embodiment 2, first wirings for vertical transfer electrode use 16 are arranged so as to extend in the horizontal direction between photoelectric conversion elements arranged in the vertical direction, and the two first wirings 16 are provided in each horizontal row. Areas where the first wirings for vertical transfer electrode use 16 overlap the vertical charge-transfer sections 5 constitute electrodes. Thus, the areas form two electrodes for each of the photoelectric conversion elements 4. Each of the second wirings for vertical transfer electrode use 17 is formed between and above two of the first wirings for vertical transfer electrode use 16, and is disposed in such a manner that the upstream end portion of the second wiring for vertical transfer electrodes 17 overlaps the downstream end portion of the upstream-side first wiring for vertical transfer electrodes 16, and the downstream end portion of the second wiring for vertical transfer electrodes 17 overlaps the upstream end portion of the downstream-side first wiring for vertical transfer electrodes 16.

Third wirings for vertical transfer electrode use 12 are formed in a shape similar to the second wirings for vertical transfer electrode use 7 of the embodiment 1. That is, when observing one of the photoelectric conversion elements 4, a third wiring for vertical transfer electrodes 12 is formed so as to extend from the intermediate portion of a second wiring for vertical transfer electrodes 17 corresponding to this photoelectric conversion element 4 to the downstream end of the second wiring 17 while facing the second wiring for vertical transfer electrodes 17 via the insulating film, and subsequently so as to extend from the downstream end to the upstream end portion of a first wiring for vertical transfer electrodes 16 corresponding to a photoelectric conversion element 4 disposed just downstream while facing the upstream end portion.

Since an area where each of wirings for vertical transfer electrode use overlaps one of the vertical charge-transfer sections constitutes an electrode, four electrodes are provided for each of the photoelectric conversion elements 4 in this embodiment. Since the first wirings for vertical transfer electrode use 16 are provided in recesses 11, the difference in level between the first wirings for vertical transfer electrode use 16 and the semiconductor substrate can be reduced as compared with the conventional one. As a result, the distance between the photoelectric conversion elements 4 and the microlens can be reduced, so that the sensitivity of the CCD image sensor can be increased. The configuration resulting in this effect is, in other words, the configuration in which the first wirings for vertical transfer electrode use 16 are arranged in the same layer as the photoelectric conversion elements 4 and the vertical charge-transfer sections 5.

In order to increase the sensitivity, it is preferred to planarize such that the surface of the semiconductor substrate and the surfaces of the first wirings for vertical transfer electrode use 16 are in the same plane. As a result, taking no account of the gate oxide film, the upper surface of the first wirings for vertical transfer electrode use 16 aligns with the lower surface of the second wirings for vertical transfer electrode use 17, and thus the distance between the photoelectric conversion elements 4 and the microlens can be further reduced.

A manufacturing method of the CCD image sensor of embodiment 2 will be described below. Up to the process of forming the second wirings for vertical transfer electrode use 17, the same procedures as the embodiment 1 are carried out. Next, a gate oxide film is formed, and a polycrystalline silicon film which will be third wirings for vertical transfer electrode use 12 is then deposited by CVD, and subsequently third wirings for vertical transfer electrode use 12 are formed by patterning, etching, doping, etc. Subsequently, procedures from forming the light-blocking film to forming the microlens similar to those described in the embodiment 1 are executed.

Also in the case that three layers of wirings for vertical transfer electrode use are formed, the distance between the microlens and the semiconductor substrate can be reduced more than that of a CCD image sensor manufactured by a conventional method.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A solid-state image pickup device in which a light-receiving section having photoelectric conversion elements arranged in a matrix form, and a vertical charge-transfer section for transferring signal charges in the vertical direction along photoelectric conversion element columns of the light-receiving section are formed on a semiconductor substrate, and which has more than two layers of wirings for vertical transfer electrode use provided on the vertical charge-transfer section via insulating films along the transfer direction, wherein groove-like recesses are formed on the surface of the semiconductor substrate, first wirings for vertical transfer electrode use are disposed in the groove-like recesses, and the surface of the semiconductor substrate and the upper surfaces of the first wirings for vertical transfer electrode use are on the same plane.

2. A solid-state image pickup device comprising a light-receiving section having photoelectric conversion elements arranged in a matrix form, and more than two layers of wirings for vertical transfer electrode use provided along the transfer direction in order to transfer signal charges in the vertical direction along photoelectric conversion element columns of the light-receiving section, wherein the first wirings for vertical transfer electrode use include areas positioned at the same depth below a surface of a semiconductor substrate as that of both the photoelectric conversion elements and the vertical charge-transfer sections facing wirings other than the first wirings for vertical transfer electrode use.

3. A manufacturing method of a solid-state image pickup device which has a light-receiving section having photoelectric conversion elements arranged in a matrix form, and a vertical charge-transfer section for transferring signal charges in the vertical direction along the photoelectric conversion element columns of the light-receiving section, and which has more than two layers of wirings for vertical transfer electrode use provided on the vertical charge-transfer section via insulating films along the transfer direction, the method comprising a process of forming groove-like recesses on a semiconductor substrate, and a process of forming the first wirings for vertical transfer electrode use in the groove-like recesses.

4. The manufacturing method of a solid-state image pickup device as claimed in claim 3, further comprising a process of aligning the upper surfaces of the first wirings for vertical transfer electrode use with the surface of the semiconductor substrate in the same plane by chemical and mechanical polishing.
